(19) United States
(12) Patent Application Publication
(10) Pub. No.: US 2016/0161979 A1
(43) Pub. Date: Jun. 9, 2016

(54) Process Skew Resilient Digital CMOS Circuit

(71) Applicant: Stichting IMEC Nederland, Eindhoven (NL)

(72) Inventor: Tobias Gemmeke, Eindhoven (NL)

(73) Assignee: Stichting IMEC Nederland, Eindhoven (NL)

(21) Appl. No.: 14/959,518

(22) Filed: Dec. 4, 2015

(30) Foreign Application Priority Data
Dec. 5, 2014 (EP) 14196607.7

(51) Int. Cl. G06F 1/10; H02M 3/10; H03K 5/159

(52) U.S. Cl. CPC G06F 1/10; H03K 5/159; H02M 3/10

(57) ABSTRACT

A digital CMOS circuit comprising at least one pull-up circuit arranged, when in an on-state, to switch an output node of the digital CMOS circuit from a first voltage level to a second voltage level within a rising transition delay. The digital CMOS circuit further comprises at least one pull-down circuit arranged, when in an on-state, to switch the voltage level of the output node of the digital CMOS circuit from the second voltage level to the first voltage level within a falling transition delay. The digital CMOS circuit further comprises at least one performance matching transistor serially connected to the first and second type transistors, the gate terminal of which is connected to biasing means arranged for biasing the at least one performance matching transistor in such a way so as to compensate for the performance mismatch between the at least one first and second type transistors.

### CROSS-REFERENCE TO RELATED APPLICATION

The present application is a non-provisional patent application claiming priority to European Patent Application No. 14196607.7 filed Dec. 5, 2014, the contents of which are hereby incorporated by reference.

### TECHNICAL FIELD

The present disclosure relates to digital CMOS circuits and more specifically to a process skew resilient digital CMOS circuit arrangement by which performance mismatch can be compensated for.

### BACKGROUND

Advanced semiconductor fabrication techniques have resulted in the fabrication of devices, such as transistors, with continually decreasing feature sizes having a substantial amount of so called process variations. These process variations are due to the inability of accurately printing geometrical features and the inability to correctly control the diffusion of dopants. The presence of process variations translates to variations in key electrical parameters of the devices, which in turn leads to variations in the electrical performance of the fabricated devices.

Process variations of the fabricated devices may be analyzed using the process corners technique, which represents the extremes of these parameter variations within which the fabricated device must function correctly. The process variations using the process corners analysis technique may be differentiated between so called straight corners and skewed corners. Using the example of a CMOS circuit device designed using NMOS and PMOS transistors, the straight corners refer to process variations where both NMOS and PMOS transistors experience similar changes in device performance, e.g., slow-slow, fast-fast, or typical-typical. On the other hand, using the same example, in the skewed corners the NMOS and PMOS transistors experience opposite changes in device performance, e.g., slow-fast, fast-slow, etc. A CMOS circuit device operating in skewed corners may lead to imbalanced timing paths and reduced operating noise margins, which may lead to inefficient implementations and ultimately limit the voltage scaling potential. For example, an inverter CMOS circuit operating in skewed corners may experience a delay mismatch between the rising and falling transitions of the inverter output due to the performance mismatch between the NMOS and PMOS transistors.

Current CMOS design techniques compensate for the effects of process variations in CMOS circuit devices operating in skewed corners by using a biasing technique, whereby the bulk terminal connection of the transistor is biased to a predetermined voltage level so as to adjust the performance of the NMOS and PMOS devices. However, such a solution substantially increases the power consumption requirements of the CMOS devices, which is an undesirable effect in the design of low-power digital circuits. Moreover, new CMOS devices, such as finFET or tunnel FET devices, do not feature an explicit bulk terminal, thus their performance cannot be adjusted using the biasing technique.

In the absence of a bulk terminal connection, the effects of process variation in CMOS devices operating in skewed corners may be compensated for by increasing the size of the transistors. For example, in a 90 nm CMOS process technology a PMOS/NMOS width ratio of 11 may be necessary for achieving the best noise margin at low-voltage. However, increasing the size of the transistors results in a substantial increase of the area overhead and power consumption of the digital circuit, which is undesirable for the design of high density and low power digital circuits.

### SUMMARY OF THE DISCLOSURE

The present disclosure provides a digital CMOS circuit arrangement in which the effects of process variation in digital CMOS circuits operating in skewed corners may be compensated for in an alternative way, as compared with conventional techniques.

According to embodiments of the present disclosure, a digital CMOS circuit arrangement is provided. The digital CMOS circuit arrangement is provided with at least one pull-up circuit, which comprises at least one transistor of a first type. The first type transistor is operable between an on-state and an off-state based on a predetermined voltage level supplied to a gate terminal of the at least one first type transistor. The pull-up circuit is arranged when the at least one first type transistor is in the on-state to switch an output node of the digital CMOS circuit arrangement from a first voltage level to a second voltage level within a rising transition delay.

The digital CMOS circuit arrangement is further provided with at least one pull-down circuit, which comprises at least one transistor of a second type. The second type transistor is operable between an on-state and an off-state based on a predetermined voltage level supplied to a gate terminal of the at least one second type transistor. The pull-down circuit is arranged when the at least one second type transistor is in the on-state to switch the voltage level of the output node of the digital CMOS circuit arrangement from the second voltage level to the first voltage level within a falling transition delay, which is different from the rising transition delay of the pull-up circuit. The delay difference between the rising and falling transition compensates for a performance mismatch between the first and second type transistors. The performance mismatch may be due to the effects of process variation, which would cause the digital CMOS circuit arrangement to operate in skewed corners.

The first and second type transistors may be serially connected at the output node of the digital circuit. For example, the drain terminal of the first type transistor may be connected to the drain terminal of the second type transistor. The digital CMOS circuit arrangement may comprise at least one performance matching transistor, which may be serially connected to the first and second type transistors. For example, the performance matching transistor may be provided between the first type and second type transistors. The gate terminal of the at least one matching performance transistor may be connected to biasing means arranged for biasing the at least one performance matching transistor in such a way so as to compensate for the performance mismatch between the at least one first and second type transistors.

It has been found that the use of a performance matching transistor can overcome, or reduce the need to compensate for, the effects of process variation by means of biasing or transistor sizing and provide an alternative way to ensure reliable device operation for digital CMOS devices operating in skewed process corners. The introduction of the performance matching transistor in the digital CMOS circuit arrangement may ensure that the pull-up and pull-down circuits experience the same process skew. Therefore, connecting the performance matching transistor in series with the first and second type transistors may ensure that the pull-up path follows the same process variation trend, either slow or fast, as the pull-down path. As a result, the introduction of the performance matching transistor can cause the digital CMOS device to operate in the straight corners instead of the skewed corners so that the first type and second type transistors experience similar changes in device performance, e.g., slow-slow, fast-fast, etc., which may lead to the development of process skew resilient logic families.

According to embodiments of the present disclosure, the biasing means may be arranged for supplying a predetermined fixed voltage to the gate terminal of the performance matching transistor so that the performance matching transistor is maintained in the on-state. This may have as a result that the operation of the digital CMOS circuit may be better controlled, since in this configuration the on-current for the pull-up and pull-down paths are determined by the performance matching transistor rather than the transistors of the pull-up and pull-down circuits. Furthermore, the fixed voltage may be supplied directly from the power supply of the circuit, e.g., V_{DD} or V_{SS}, thereby minimizing the need for providing additional inputs for supplying the biasing voltage. Moreover, in the case where an additional input is provided, the fixed voltage may be regulated so as to ensure better compensation for the process variation effects. For example, this may be achieved by providing a control voltage to the performance matching transistor, which may be adapted based on the parametric variations determined by the manufacturing process, supply voltage variations, or temperature.

According to embodiments of the present disclosure, the biasing means may comprise an inverter circuit, the output of which is connected to the gate terminal of at least one performance matching transistor. The use of an inverter to control the switching activity of the matching performance transistor may improve the on-to-off current ratio of the corresponding pull-up and pull-down circuits. As a result, the use of the inverter may greatly simplify the process of identifying the optimal width ratio between the different transistors of the digital CMOS circuit. This is because, in this configuration, the on and off-currents of the pull-up and pull-down paths can be controlled by means of the inverter. As a result, a better on-to-off current ratio can be achieved between the pull-up and pull-down network by controlling both transitions between on and off states. Therefore, by controlling both the on and off currents of the pull-up and pull-down paths, the process of identifying the optimal width ratio for the transistors in the pull-down and pull-up paths is greatly simplified.

According to embodiments of the present invention, the ratio of the size, e.g., the transistor width and/or length, between the first and second type transistors may be chosen such that a predetermined device performance is achieved in combination with the presence of the performance matching transistor. For example, the width of the first type transistor may be at least equal to the size of the second type transistor, which ensures low area overhead of the digital CMOS circuit. The size of the first type transistor may, for example, be at most three times the size of the second type transistor so as to ensure faster device performance. This size relationship between the first and second type transistors is achievable due to the presence of the performance matching transistor.

### BRIEF DESCRIPTION OF THE DRAWINGS

FIG. 1 shows an example of a digital CMOS circuit according to prior art.

FIGS. 2-8 show examples of digital CMOS circuits according to example embodiments.

FIGS. 9 and 10 show examples of sizing ratios between pull-up and pull-down transistors according to example embodiments.

### DETAILED DESCRIPTION

The present disclosure will be described with respect to particular embodiments and with reference to certain drawings, but the disclosure is not limited thereto, rather only by the claims. The drawings described are only schematic and are non-limiting. In the drawings, the size of some of the elements may be exaggerated and not drawn to scale for illustrative purposes. The dimensions and the relative dimensions do not necessarily correspond to actual reductions to practice of the disclosure.

Furthermore, the terms first, second, third, and the like in the description and in the claims are used for distinguishing between similar elements and not necessarily for describing a sequential or chronological order. The terms are interchangeable under appropriate circumstances, and the embodiments of the disclosure can operate in other sequences than described or illustrated herein.

Moreover, the terms top, bottom, over, under, and the like in the description and the claims are used for descriptive purposes and not necessarily for describing relative positions. The terms so used are interchangeable under appropriate circumstances, and the embodiments of the disclosure described herein can operate in other orientations than described or illustrated herein.

Furthermore, the various embodiments, perhaps referred to as “preferred,” are to be construed as example embodiments in which the disclosure may be implemented rather than as limiting the scope of the disclosure.

The term “comprising,” used in the claims, should not be interpreted as being restricted to the elements or steps listed thereafter; it does not exclude other elements or steps. It needs to be interpreted as specifying the presence of the stated features, integers, steps or components as referred to, but does not preclude the presence or addition of one or more other features, integers, steps or components, or groups thereof. Thus, the scope of the expression “a device comprising A and B” should not be limited to devices consisting only of components A and B, rather with respect to the present disclosure, the only enumerated components of the device are A and B, and further the claim should be interpreted as including equivalents of those components.

As used herein, the term “transistor size” is intended to mean the area occupied by the transistor designed in a specific process technology. The size of the transistor is defined by its dimensions, e.g., width, length, or height, which can be adapted to meet a predetermined electrical performance characteristic.

As used herein, the term “size ratio” is intended to mean the transistor size comparison between NMOS and PMOS transistors of a digital CMOS circuits.

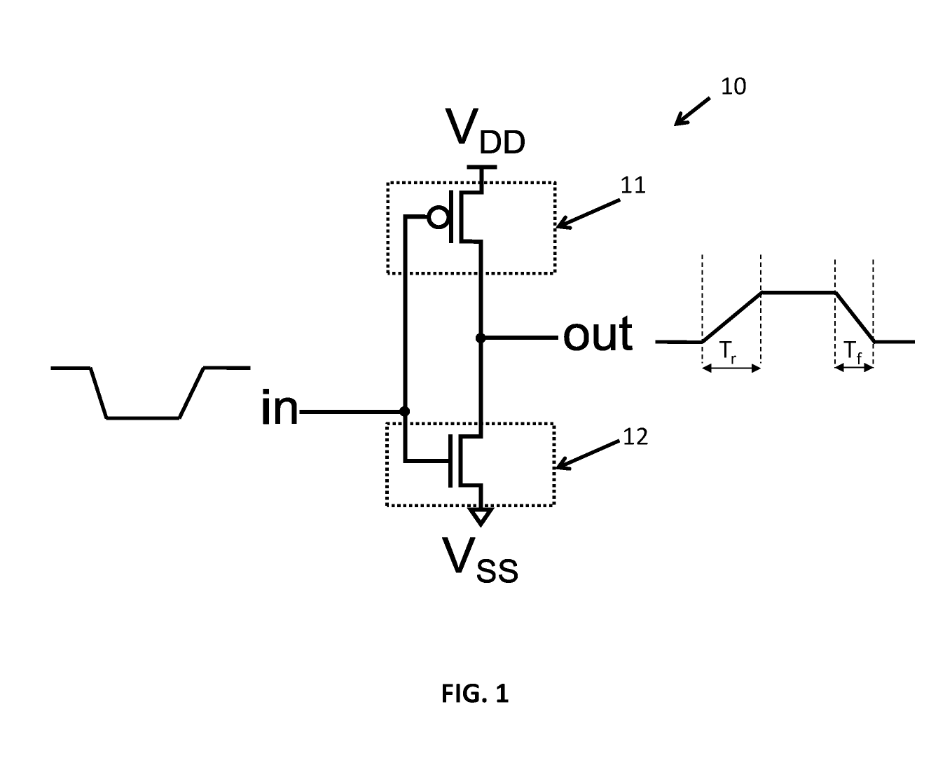

Embodiments of the present disclosure may be described with the aid of the example digital CMOS circuits shown in FIGS. 1 to 10.

FIG. 1 shows an example of a prior art digital CMOS circuit device 10 comprising a pull-up circuit 11 and a pull-down circuit 12, each respectively comprising at least one first type transistor, e.g., PMOS, and at least one second type transistor, e.g., NMOS transistor, the gate terminals of which are connected to a common input node.

The pull-up circuit 11 and pull-down circuit 12 are operable between an on-state and an off-state depending on the voltage level supplied to the gate terminal of the corresponding first and second type transistors. For example, in the case of a CMOS inverter, the pull-up circuit 11 may be activated by supplying to the gate terminal of the PMOS transistor a first voltage level, e.g., a low voltage equal to the V_{SS} voltage, while the pull-down circuit 12 may be activated by supplying to the gate terminal of the NMOS transistor a second voltage level, e.g., a high voltage level equal to the V_{DD} voltage.

Depending on which one of the pull-up 11 or pull-down 12 circuits is activated, the voltage at the output node will switch to the corresponding voltage level within a predetermined transition delay. For example, in the case where a low voltage level is supplied to the input node, the pull-up circuit 11 will be activated, causing the voltage at the output node to switch from a low voltage level to a high voltage level within a rising transition delay Tᵣ. In the case where the pull-down circuit 12 is activated instead, the output voltage at the output node will switch from a high voltage level to a low voltage level within a falling transition delay T_{f}.

In a CMOS digital circuit operating in straight process corners, e.g., slow-slow, fast-fast, etc., the rising Tᵣ and falling T_{f} transition delays may be substantially equal since the transistors in the pull-up 11 and pull-down 12 circuits experience same changes in electrical performance. However, in the case where the CMOS circuit 10 operates in the skewed process corners, the rising Tᵣ and falling T_{f} transition delays may not be equal due to the electrical performance mismatch between the transistors in the pull-up 11 and pull-down 12 circuits, as shown in FIG. 1. A CMOS circuit device operating in skewed corners may lead to imbalanced timing paths and reduced operating noise margins, which may lead to inefficient implementations and ultimately limit the voltage scaling potential.

To compensate for the effects of process variation in digital CMOS circuits operating in skewed corners, the CMOS circuit arrangement of the present disclosure may be used. According to embodiments of the present disclosure, a performance matching transistor may be serially connected to the at least one first type transistor, e.g., PMOS, of the pull-up circuit and the at least one second type transistor, e.g., NMOS, of the pull-down circuit. The gate terminal of the performance matching transistor may be connected to biasing means arranged for biasing the at least one performance matching transistor in such a way so as to compensate for the performance mismatch between the at least one first and second type transistors. As a result, with the digital CMOS circuit arrangement of the present invention, the process variation effects of a CMOS circuit operating in skewed corners may be compensated for without the need for explicit bulk terminal connection or substantially increasing the size, e.g., width and/or length, of the transistors in the pull-up and pull-down circuits.

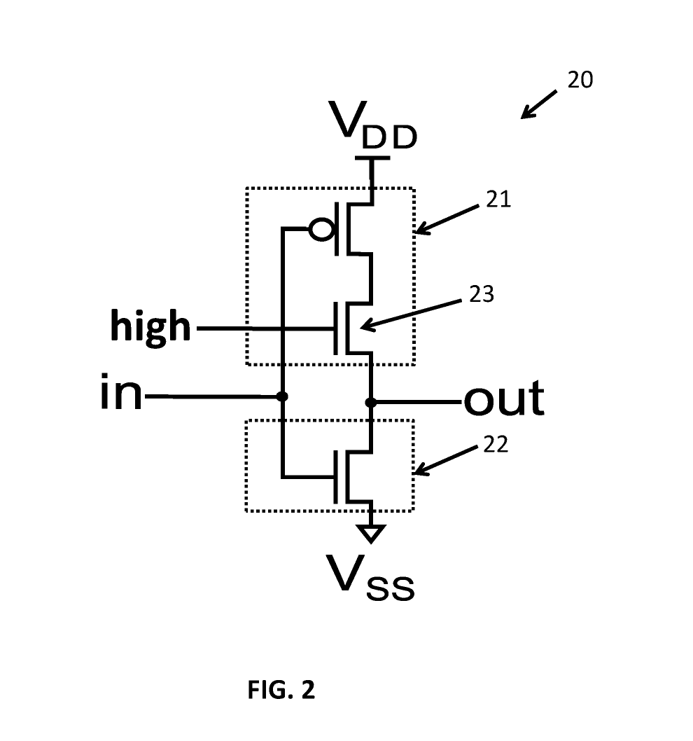

FIG. 2 shows an example of a digital CMOS circuit 20 according to embodiments of the present disclosure. In this case, a CMOS inverter 20 operating in a similar manner to the CMOS inverter 10 of FIG. 1 may be used as an example.

The CMOS inverter 20 may be implemented as a skew resilient logic circuit so as to compensate for the effects of process variation by matching the electrical performance of the pull-down circuit 22 with the pull-up circuit 21. This may be achieved by providing a performance matching transistor 23 of an N-type in the pull-up circuit 21 between the PMOS transistor and the output node of the CMOS inverter 20. The NMOS performance matching transistor 23 in the pull-up path may cause the pull-up circuit 21 to experience the same process skew as the pull-down circuit 22, thereby causing the pull-up path to follow the same process variation trend, either slow or fast, as the pull-down path.

The gate terminal of the NMOS performance matching transistor 23 may be connected to biasing means arranged for supplying a fixed voltage, e.g., V_{DD}, so that the performance matching transistor may be maintained in the on-state. For example, the fixed voltage may be supplied directly from the power supply of the circuit, e.g., V_{DD} or V_{SS}, thereby minimizing the need for providing additional inputs for supplying the biasing voltage.

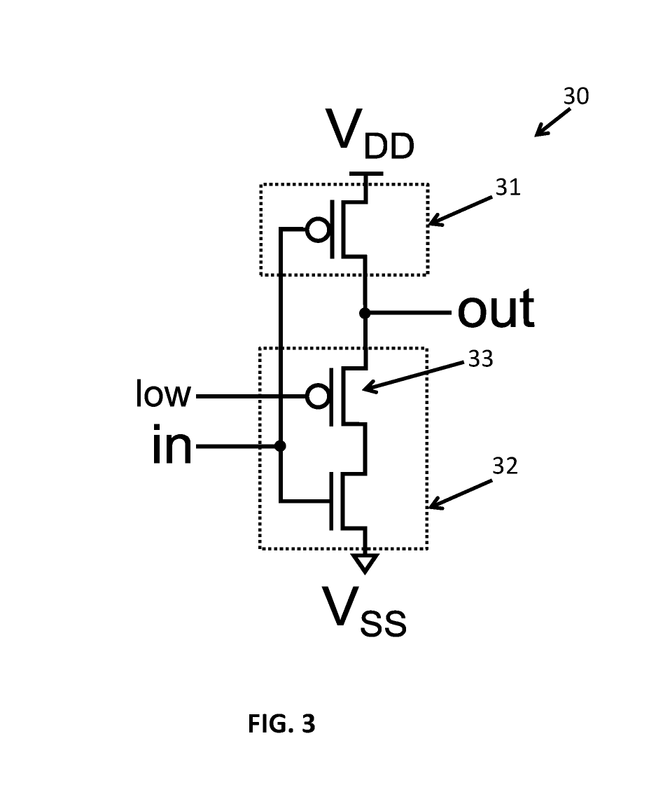

According to embodiments of the present disclosure, in order to match the electrical performance of the pull-up circuit with the pull-down circuit, a PMOS performance matching transistor may be provided in the pull-down circuit of a digital CMOS device. FIG. 3 shows a digital CMOS device, such as a CMOS inverter 30 operating in a similar manner to the one presented in FIG. 2.

The CMOS inverter 30 may be implemented as a skew resilient logic circuit so as to compensate for the effects of process variation by matching the electrical performance of the pull-up circuit 31 with the pull-down circuit 32. This may be achieved by providing a performance matching transistor 33 of a P-type in the pull-down circuit 32 between the NMOS transistor and the output node. The PMOS performance matching transistor 33 in the pull-down path may cause the pull-down circuit 32 to experience the same process skew as the pull-up circuit 31, thereby causing the pull-down path to follow the same process variation trend, either slow or fast, as the pull-up path.

The gate terminal of the PMOS performance matching transistor 33 may be connected to biasing means arranged for supplying a fixed voltage, e.g., Vss, so that the performance matching transistor 33 may be maintained in the on-state. For example, the fixed voltage may be supplied directly from the power supply of the circuit, e.g., V_{DD} or V_{SS}, thereby minimizing the need for providing additional inputs for supplying the biasing voltage.

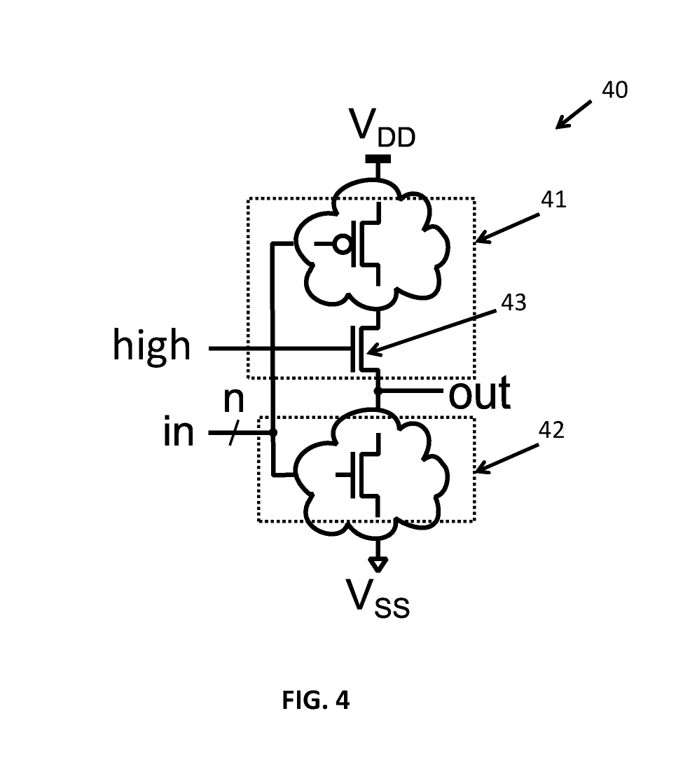

According to embodiments of the present invention, the digital CMOS circuit arrangement according to the present disclosure may be used with digital CMOS circuits having multiple inputs for matching the electrical performance of the pull-down circuit with the pull-up circuit and vice versa, as shown in FIG. 4.

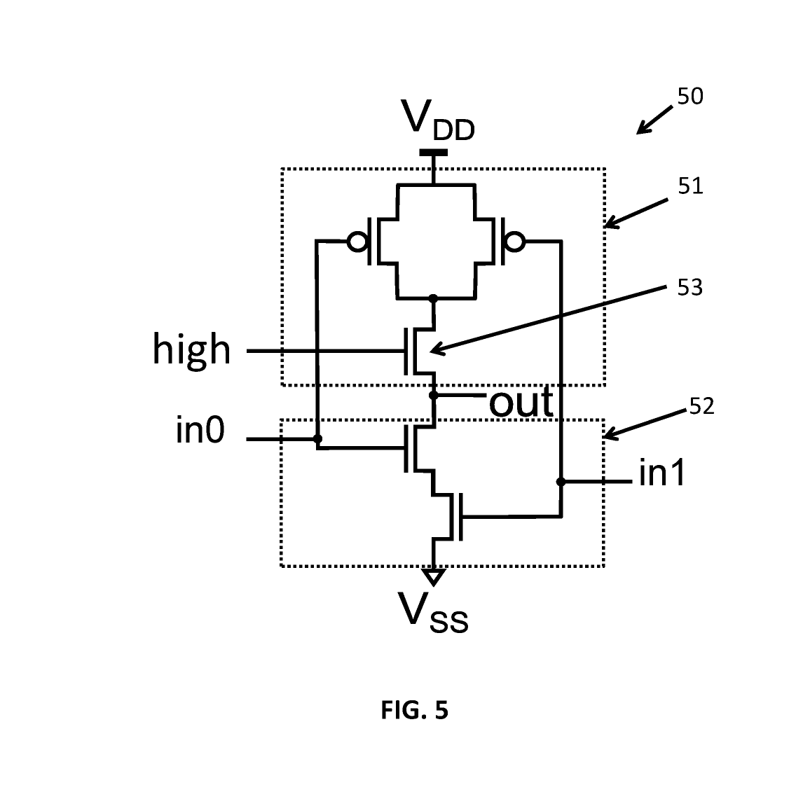

For example, as shown in FIG. 5, a two-input CMOS AND logic gate 50 may be implemented as a skew resilient logic circuit so as to compensate for the effects of process variation by matching the electrical performance of the pull-down circuit 52 with the pull-up circuit 51. This may be achieved by providing at least one NMOS type performance matching transistor 53 between the PMOS transistors of the pull-up circuit 51 and the output node. For example, the NMOS performance matching transistor 53 may be serially connected to the PMOS transistors of the pull-up circuit 51 and to the NMOS transistors of the pull-down circuit 52.

In the exemplified circuit arrangement shown in FIG. 5, the drain terminal of the at least one NMOS performance matching transistor 53 may be connected to the drain terminals of the PMOS transistors of the pull-up circuit 51, while the source terminal of the NMOS performance matching transistor 53 may be connected to the drain terminal of at least one of the NMOS transistor of the pull-down circuit 52. The NMOS performance matching transistor 53 in the pull-up path may cause the pull-up circuit 51 to experience the same process skew as the pull-down circuit 52, thereby causing the pull-up path to follow the same process variation trend, either slow or fast, as the pull-down path.

The gate terminal of the NMOS performance matching transistor 53 may be connected to biasing means arranged for supplying a fixed voltage, e.g., V_{DD}, so that the performance matching transistor may be maintained in the on-state. For example, the fixed voltage may be supplied directly from the power supply of the circuit, e.g., V_{DD} or V_{SS}, thereby minimizing the need for providing additional inputs for supplying the biasing voltage.

It should be noted that, similarly to previous embodiments, the CMOS AND logic gate 50 may be implemented as a skew resilient logic circuit so as to compensate for the effects of process variation by matching the electrical performance of the pull-up circuit 51 with the pull-down circuit 52 by providing a performance matching transistor 33 of a P-type in the pull-down circuit 52 between the NMOS transistors and the output node.

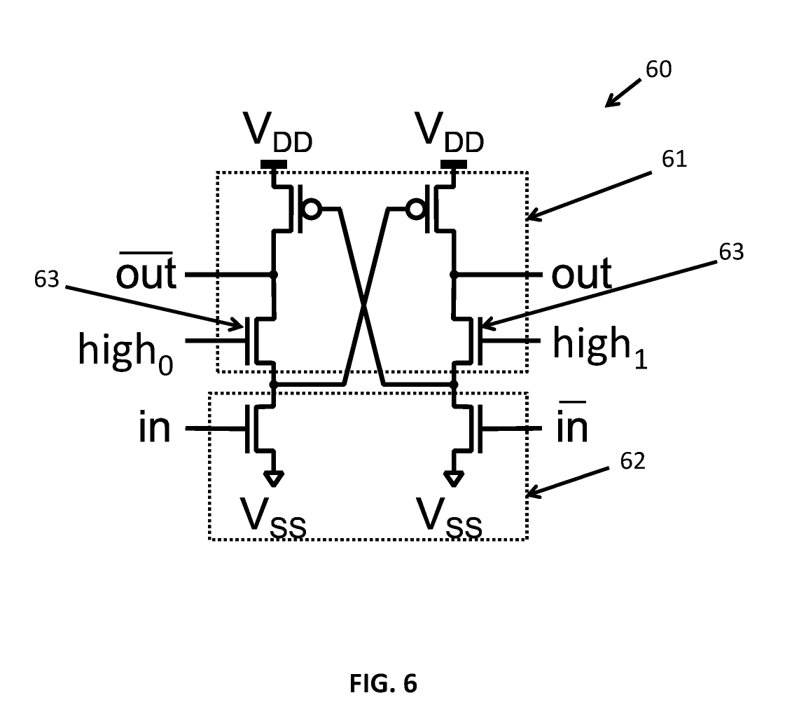

According to embodiments of the present invention, as shown in FIG. 6, a Cascode Voltage Switch Logic (CVSL) 60 may be implemented as a skew resilient logic circuit so as to compensate for the effects of process variation by matching the electrical performance of the pull-down circuit 62 with the pull-up circuit 61. In this case, two NMOS performance matching transistors 63 may be provided in the pull-up path, which may be serially connected to the PMOS transistors in the pull-up path. In this configuration, the two NMOS performance matching transistors 63 in the pull-up path will experience the same process skew as the NMOS transistors in the pull-down circuit 62, causing the pull-up path to follow the same process corner trend, e.g., slow-slow or fast-fast, as the pull-down path.

The gate terminal of each of the NMOS performance matching transistors 63 may be connected to biasing means arranged for supplying a fixed voltage, e.g., V_{DD}, so that the performance matching transistor may be maintained in the on-state. For example, the fixed voltage may be supplied directly from the power supply of the circuit, e.g., V_{DD} or V_{SS}, thereby minimizing the need for providing additional inputs for supplying the biasing voltage.

It should be noted that, similarly to previous embodiments, the CSVL circuit 60 may be implemented as a skew resilient logic circuit so as to compensate for the effects of process variation by matching the electrical performance of the pull-up circuit 61 with the pull-down circuit 62 by providing performance matching transistors 63 of a P-type in the pull-down circuit 62, which may be serially connected to the NMOS transistors of the pull-down circuit 62.

According to embodiments of the present disclosure, the present disclosure may be used for the development of skew resilient CMOS logic families, such as logic gates or other circuits, having lower area overhead and reduced propagation delay than comparable standard CMOS implementations.

According to embodiments of the present disclosure, the biasing means may be provided by an inverter, the output of which may be connected to the gate terminal of the performance matching transistor. The inverter may be used to control the switching activity of the matching performance transistor so as to improve the on-to-off current ratio of the corresponding pull-up and pull-down circuits. For example, the inverter circuit may be used for power gating the digital CMOS circuit so as achieve a leakage power reduction, which may lead to the scaling of the operating voltage and/or process skew of the digital CMOS circuit due to the improved on-to-off ratio.

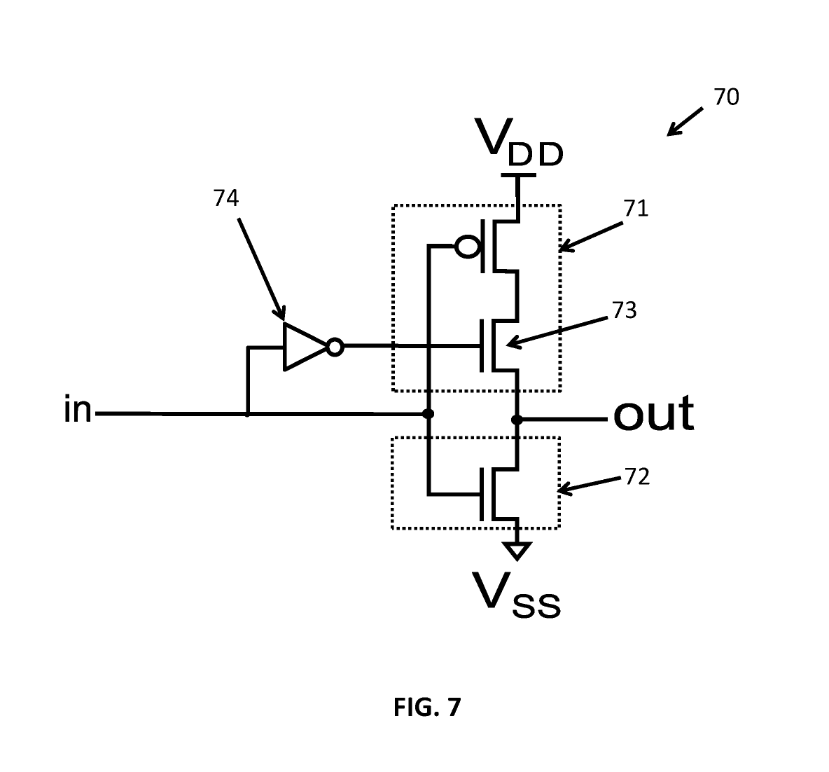

For example, as shown in FIG. 7, a CMOS inverter 70 may be implemented as a skew resilient logic circuit so as to compensate for the effects of process variation by matching the electrical performance of the pull-down circuit 72 with the pull-up circuit 71. As previously discussed, this may be achieved by providing a performance matching transistor 73 of an N-type in the pull-up circuit 71 between the PMOS transistor and the output node. The NMOS performance matching transistor 73 in the pull-up path may cause the pull-up circuit 71 to experience the same process skew as the pull-down circuit 72, thereby causing the pull-up path to follow the same process variation trend, either slow or fast, as the pull-down path.

The gate terminal of the NMOS performance matching transistor 73 may be connected to the output of an inverter 74, which may be part of the biasing means, the input of which may connected to the gate terminal of at least one of the transistors in the pull-up 71 or pull-down circuit 72. For example, as shown in FIG. 7, the input of the inverter 74 is connected to the input node of the CMOS inverter 70, so that when the input voltage supplied to the input node of the CMOS inverter 70 switches from a high voltage, e.g., V_{DD}, to a low voltage, e.g., Vss, the NMOS performance matching transistor 73 switches from the off-state to the on-state, thereby causing the pull-up path to follow the same process corner trend with that of the pull-down path. In contrast, when the input voltage supplied to the input node of the CMOS inverter 70 switches from a low voltage, e.g., Vss, to a high voltage, e.g., V_{DD}, the NMOS performance matching transistor 73 switches from the on-state to the off-state, thereby reducing the leakage power of the CMOS inverter 70, which may lead to the scaling of the operating voltage and/or process skew due to the improved on-to-off current ratio.

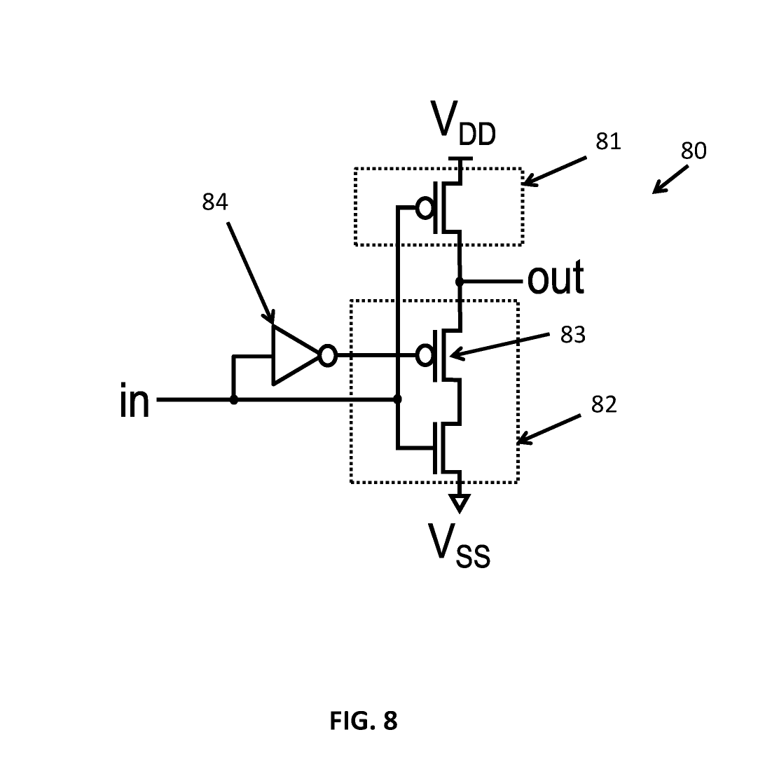

Similarly, as shown in FIG. 8, an inverter 84 may be used to control the switching activity of a PMOS performance matching transistor 83 provided in a pull-down circuit 82 of a circuit device, such as CMOS inverter 80, implemented as a skew resilient logic circuit so as to compensate for the effects of process variation by matching the electrical performance of the pull-up circuit 81 with the pull-down circuit 82.

In this case, the gate terminal of the PMOS performance matching transistor 83 may be connected to the output of an inverter 84, which may be part of the biasing means, the input of which may be connected to the gate terminal of at least one of the transistors in the pull-up circuit 81 or pull-down circuit 82. For example, as shown in FIG. 8, the input of the inverter 84 is connected to the input node of the CMOS inverter 80, so that when the input voltage supplied to the input node of the CMOS inverter 80 switches from a low voltage, e.g., Vss, to a high voltage, e.g., V_{DD}, the PMOS performance matching transistor 83 switches from the off-state to the on-state, thereby causing the pull-down path to follow the same process corner trend with that of the pull-up path. In contrast, when the input voltage supplied to the input node of the CMOS inverter 80 switches from a high voltage, e.g., V_{DD}, to a low voltage, e.g., Vss, the PMOS performance matching transistor 83 switches from the on-state to the off-state, thereby reducing the leakage power of the CMOS inverter 80, which may lead to the scaling of the operating voltage and/or process skew due to the improved on-to-off current ratio.

According to embodiments of the present disclosure, the use of the inverter circuit to control the switching activity of the performance matching transistor greatly reduces the sizing requirements of the transistors in the pull-up and pull-down circuits for achieving a predetermined device performance. This is due to the improved on-to-off current ratio, which may result in the size ratio between the transistors of the pull-up and pull-down circuits being smaller than comparable standard CMOS implementations. This is because, in this configuration, the on-current and off-current of the pull-up and pull-down paths can be controlled by means of the inverter.

Therefore, by controlling both the on-current and off-current of the pull-up and pull-down paths, the process of identifying the optimal width ratio for the transistors in the pull-down and pull-up paths is greatly simplified. For example, the size, e.g., the transistor width and/or length, ratio between the transistors of the pull-up and pull-down circuits may be chosen such that a predetermined device performance may be achieved in combination with the presence of the performance matching transistor.

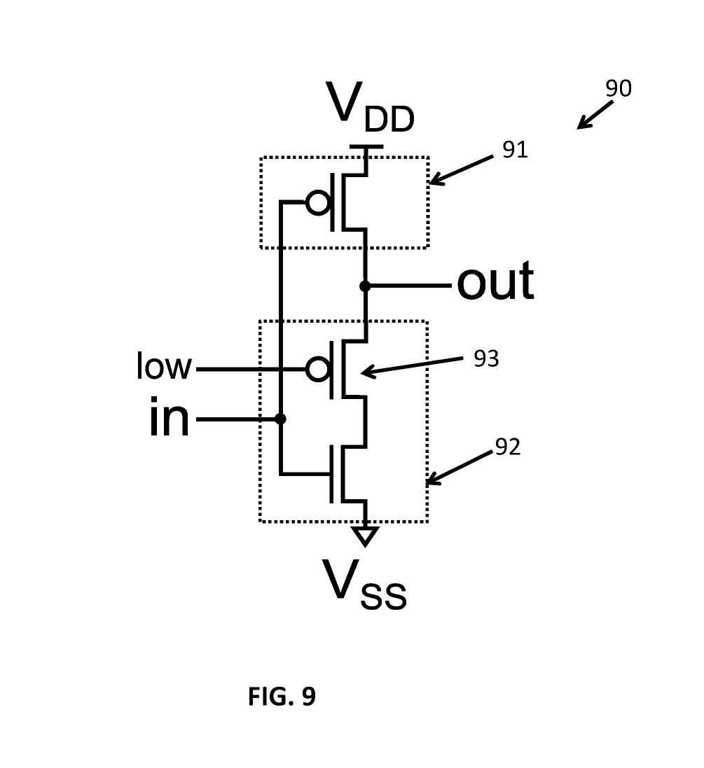

For example, as shown in FIG. 9, a CMOS digital circuit 90, such as a CMOS inverter may be implemented as a skew resilient logic circuit according to embodiments of the present invention, so as to compensate for the effects of process variation by matching the electrical performance of the pull-up circuit 91 with the pull-down circuit 92. This may be achieved by providing a PMOS performance matching transistor 93 between the at least one NMOS transistor of the pull-down circuit 92 and the output node of the CMOS digital circuit 90. In this case, the transistor sizes for the NMOS and PMOS transistors in digital CMOS circuit may be selected to be equal.

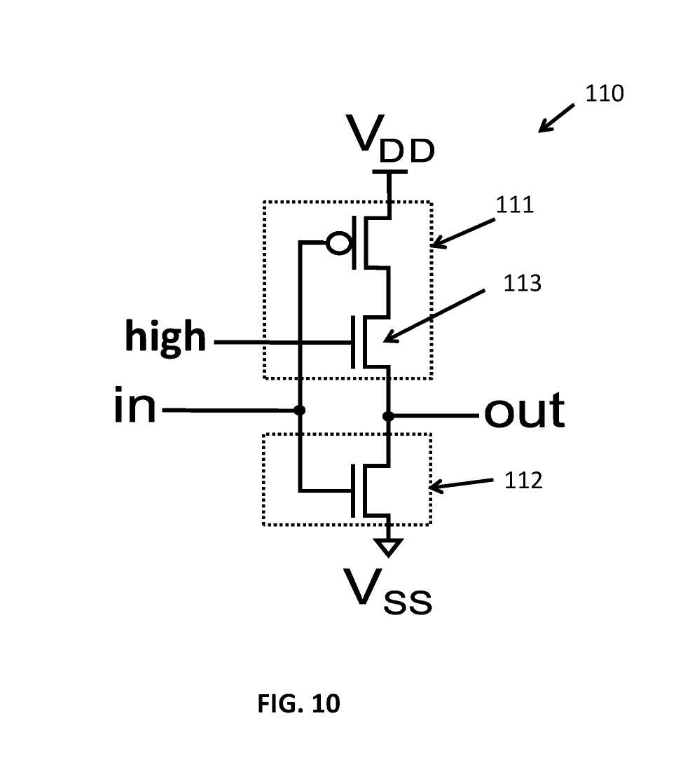

In a further example, as shown in FIG. 10, a CMOS digital circuit 110, such as a CMOS inverter, may be implemented as a skew resilient logic circuit according to embodiments of the present invention, so as to compensate for the effects of process variation by matching the electrical performance of the pull-down circuit 112 with the pull-up circuit 111. This may be achieved by providing an NMOS performance matching transistor 113 between the PMOS transistors of the pull-up circuit 111 and the output node of the CMOS digital circuit 110. In this case, the size of the PMOS transistors of the digital CMOS circuit 110 may be at most three times the size selected for the NMOS transistors of the digital CMOS circuit 110.

According to embodiments of the present disclosure, digital CMOS circuits may be implemented with transistors that have no explicit bulk terminal connections. For example, the transistors in the pull-up and pull-down circuits and the at least one performance matching transistor may be multi-gate transistors such as finFET, tunnel field-effect transistors, or the like.

What is claimed is:

1. A digital CMOS circuit comprising:
a pull-up circuit having at least one first transistor operable in an on-state and an off-state based on a predetermined voltage level supplied to a gate terminal of the at least one first transistor, wherein the pull-up circuit is configured to, when the at least one first transistor is in the on-state, switch an output node of the digital CMOS circuit from a first voltage level to a second voltage level within a rising transition delay associated with the at least one first transistor;
a pull-down circuit having at least one second transistor operable in an on-state and an off-state based on a predetermined voltage level supplied to a gate terminal of the at least one second transistor, wherein the pull-down circuit is configured to, when the at least one second transistor is in the on-state, switch the voltage level of the output node of the digital CMOS circuit from the second voltage level to the first voltage level within a falling transition delay associated with the at least one second transistor, wherein the falling transition delay is different from the rising transition delay, and wherein the at least one first transistor and the at least one second transistor are serially connected at the output node of the digital CMOS circuit;
a performance matching transistor serially connected to the at least one first transistor and the at least one second transistor; and
a biasing means, wherein the biasing means is configured to supply a voltage to a gate terminal of the performance matching transistor to compensate for the difference between the rising transition delay and the falling transition delay.

2. The digital CMOS circuit of claim 1, wherein the biasing means is configured to supply a fixed voltage to the gate terminal of the performance matching transistor to keep the performance matching transistor in the on-state during operation.

3. The digital CMOS circuit of claim 1, wherein the biasing means comprises an inverter circuit, wherein the output of the inverter circuit is connected to the gate terminal of the performance matching transistor, and the input of the inverter circuit is connected to the gate terminals of the first and second transistors.

4. The digital CMOS circuit of claim 1, wherein a channel width of the first transistor is equal to or greater than a channel width of the second transistor.

5. The digital CMOS circuit of claim 4, wherein the channel width of the first transistor is at most three times the channel width of the second transistor.

6. The digital CMOS circuit of claim 1, wherein the first transistor is a P-type transistor and the second transistor is an N-type transistor.

7. The digital CMOS circuit of claim 1, wherein the first transistor, the second transistor, and the performance matching transistor do not include a bulk terminal.

8. The digital CMOS circuit of claim 1, wherein the performance matching transistor is serially connected between the first transistor and the output node of the digital CMOS circuit.

9. The digital CMOS circuit of claim 8, wherein the performance matching transistor is an N-type transistor.

10. The digital CMOS circuit of claim 1, wherein the performance matching transistor is serially connected between the second transistor and the output node of the digital CMOS circuit.

11. The digital CMOS circuit of claim 10, wherein the performance matching transistor is a P-type transistor.

12. A digital CMOS circuit comprising:
a pull-up circuit comprising:
a first transistor operable in an on-state and an off-state based on a predetermined voltage level supplied to a gate terminal of the first transistor; and
a performance matching transistor serially connected to the first transistor, wherein the performance matching transistor is operable in an on-state and an off-state based on a predetermined voltage level supplied to a gate terminal of the performance matching transistor,
wherein the pull-up circuit is configured to switch an output node of the digital CMOS circuit from a first voltage level to a second voltage level when the first transistor is in the on-state and the performance matching transistor is in the on-state; and
a pull-down circuit serially connected to the pull-up circuit, wherein the pull-down circuit comprises a second transistor operable in an on-state and an off-state based on a predetermined voltage level supplied to a gate terminal of the second transistor, wherein the pull-down circuit is configured to switch the voltage level of the output node of the digital CMOS circuit from the second voltage level to the first voltage level when the second transistor is in the on-state.

13. The digital CMOS circuit of claim 12, wherein a fixed voltage is supplied to the gate terminal of the performance matching transistor to keep the performance matching transistor in the on-state during operation.

14. The digital CMOS circuit of claim 12, further comprising an inverter circuit, wherein the output of the inverter circuit is connected to the gate terminal of the performance matching transistor, and the input of the inverter circuit is connected to the gate terminals of the first and second transistors.

15. The digital CMOS circuit of claim 12, wherein the first transistor is a P-type transistor, the second transistor is an N-type transistor, and the performance matching transistor is an N-type transistor serially connected between the first transistor and the output node of the digital CMOS circuit.

16. A digital CMOS circuit comprising:
a pull-up circuit having a first transistor operable in an on-state and an off-state based on a predetermined voltage level supplied to a gate terminal of the first transistor, wherein the pull-up circuit is configured to switch an output node of the digital CMOS circuit from a first voltage level to a second voltage level when the first transistor is in the on-state; and
a pull-down circuit serially connected to the pull-up circuit, wherein the pull-down circuit comprises:
a second transistor operable in an on-state and an off-state based on a predetermined voltage level supplied to a gate terminal of the second transistor; and
a performance matching transistor serially connected to the second transistor, wherein the performance matching transistor is operable in an on-state and an off-state based on a predetermined voltage level supplied to a gate terminal of the performance matching transistor, wherein the pull-down circuit is configured to switch the output node of the digital CMOS circuit from the second voltage level to the first voltage level when the second transistor is in the on-state and the performance matching transistor is in the on state.

17. The digital CMOS circuit of claim 16, wherein a fixed voltage is supplied to the gate terminal of the performance matching transistor to keep the performance matching transistor in the on-state during operation.

18. The digital CMOS circuit of claim 16, further comprising an inverter circuit, wherein the output of the inverter circuit is connected to the gate terminal of the performance matching transistor, and the input of the inverter circuit is connected to the gate terminals of the first and second transistors.

19. The digital CMOS circuit of claim 16, wherein the first transistor is a P-type transistor, the second transistor is an N-type transistor, and the performance matching transistor is a P-type transistor serially connected between the second transistor and the output node of the digital CMOS circuit.
